(19) United States
(12) Patent Application Publication
(10) Pub. No.: US 2021/0287979 A1
(43) Pub. Date: Sep. 16, 2021

(54) INTERCONNECT STACK WITH LOW-K DIELECTRIC

(71) Applicant: Intel Corporation, Santa Clara, CA (US)

(72) Inventors: Veronica Aleman Strong, Hillsboro, OR (US); Henning Braunisch, Phoenix, AZ (US); Hiroki Tanaka, Chandler, AZ (US); Haobo Chen, Chandler, AZ (US)

(73) Assignee: Intel Corporation, Santa Clara, CA (US)

(21) Appl. No.: 16/817,309

(22) Filed: Mar. 12, 2020

(51) Int. Cl. H01L 23/498

(52) U.S. Cl. CPC H01L 23/49894; H01L 23/49811; H01L 23/49822

(57) ABSTRACT

Embodiments may relate to a microelectronic package with an interconnect stack that includes a cavity therein. The cavity may include a dielectric material with a dielectric value less than 3.9. The microelectronic package may further include first and second conductive elements in the cavity, with the dielectric material positioned therebetween. Other embodiments may be described or claimed.

### BACKGROUND

As a result of shrinking integrated circuit (IC) units, it has become desirable to achieve high-density interconnects in multi-chip packaging. It has also become desirable to shrink signal lines and signal-to-signal line distances. Although shrinking these features may help with applications such as high-bandwidth memory (HBM) by increasing density, smaller features may have an undesirable impact on resistance-capacitance (RC) delay, crosstalk, or dynamic power consumption.

### BRIEF DESCRIPTION OF THE DRAWINGS

FIG. 1 depicts a simplified top-down view of an example interconnect stack with a low-k dielectric, in accordance with various embodiments.

FIGS. 2a and 2b depict simplified cross-sectional views of the example interconnect stack with a low-k dielectric of FIG. 1, in accordance with various embodiments.

FIG. 3 depicts a simplified cross-sectional view of an alternative example interconnect stack with a low-k dielectric, in accordance with various embodiments.

FIG. 4 depicts a simplified cross-sectional view of an alternative example interconnect stack with a low-k dielectric, in accordance with various embodiments.

FIG. 5 depicts a simplified cross-sectional view of an alternative example interconnect stack with a low-k dielectric, in accordance with various embodiments.

FIG. 6 depicts a simplified cross-sectional view of an alternative example interconnect stack with a low-k dielectric, in accordance with various embodiments.

FIG. 7 depicts a simplified cross-sectional view of an alternative example interconnect stack with a low-k dielectric, in accordance with various embodiments.

FIG. 8 depicts a simplified cross-sectional view of an alternative example interconnect stack with a low-k dielectric, in accordance with various embodiments.

FIG. 9 depicts an example microelectronic package with an interconnect stack with a low-k dielectric therein, in accordance with various embodiments.

FIG. 10 depicts an example technique by which an interconnect stack with a low-k dielectric may be manufactured, in accordance with various embodiments.

FIG. 11 is a top view of a wafer and dies that may include an interconnect stack with a low-k dielectric, in accordance with various embodiments.

FIG. 12 is a side, cross-sectional view of an IC device assembly that may include an interconnect stack with a low-k dielectric, in accordance with various embodiments.

FIG. 13 is a block diagram of an example electrical device that may include an interconnect stack with a low-k dielectric, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature [[formed/deposited/disposed/etc.]] on a second feature,” may mean that the first feature is formed/deposited/disposed/etc. over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted, it has become desirable to shrink signal lines or signal-to-signal line distances in some IC units, which may have undesirable effects on factors such as RC-delay, crosstalk, or dynamic power consumption in the IC units or in microelectronic packages that include those IC units. As a result, mitigating those undesirable effects may be desirable in order to increase input/output (I/O) density on single or multiple interconnected layers.

Embodiments herein relate to reducing the capacitance-related metrics (e.g., RC-delay) through the use of dielectric materials with a relatively low dielectric constant k (also referred to as low-k or ultra-low-k or extremely low-k dielectrics) as interlayer dielectrics. Specifically, embodiments herein relate to reducing RC-delay, crosstalk, or dynamic power consumption in high-density interconnects by selectively adding air-gaps with a k value of approximately 1, a low-k dielectric or some other dielectric in place of materials with a higher dielectric constant. By doing so, embodiments herein may effectively lower the overall capacitance and improve crosstalk across multiple signal lines in an IC circuit or microelectronic package.

Generally, as used herein a low-k or ultra-low-k dielectric may refer to a dielectric material with a dielectric constant k with a value less than approximately 3.9, relative to the permittivity of vacuum that is approximately 8.85×10⁻¹² farads per meter. More generally, it may be a dielectric material with a dielectric constant k with a value less than approximately 2. In specific embodiments, the dielectric material may be air, which may have a dielectric constant k of approximately 1. More generally, the dielectric constant k of air may be between approximately 1.0001 and approximately 1.001.

In other embodiments, the dielectric material may be an inert gas such as nitrogen, argon, or some other inert gas (or combination thereof). The inert gas may also have a dielectric constant k similar to that of air (e.g., approximately 1). As used herein, an inert gas may refer to a chemically non-reactive gas, which may include nitrogen gas (e.g., N₂ (g)), argon gas (e.g., Ar (g)), or some other noble gas. It will also be understood that the term “inert gas” may relate to a gas that is made up of a single type or combination of inert substances such as nitrogen, argon, etc. An inert gas, N₂ (g) for example, may relate to a gas that is approximately 99% pure nitrogen, although in other embodiments the purity may be greater or smaller.

More specifically, specific embodiments herein relate to embedding air-gaps in high I/O routing regions by using signal lines as a pseudo hard mask to lithographically create and define air-gaps on a multi-layer stack. As used herein, a multi-layer stack may refer to an interconnect stack with a plurality of layers such as a layer with one or more signal traces, a layer with one or more down-vias, and a layer with one or more up-vias. Such a stack may be referred to as a three-layer stack. Other embodiments may include or relate to interconnect stacks with more or fewer layers. Once the air-gaps are created, a rigid (non-conforming) build-up film may be placed on the stack (e.g., through lamination) to seal the defined air-gaps.

Embodiments herein may provide a number of advantages over legacy interconnect stacks. As noted previously, the dielectric constant k of air may be approximately 1. Therefore, embedding air-gaps into an organic package may lower the overall capacitance in the high-density interconnects, and thus decrease RC-delay, crosstalk, or dynamic power consumption. Embodiments here may have a significant improvement (e.g., on the order of 57% in some simulations) in signal trace self-capacitance per unit length C measured in picofarads per meter (pF/m) over legacy interconnect stacks. Additionally, embodiments herein may exhibit an improvement in crosstalk (e.g., on the order of 14% in some simulations) between nearest-neighbor traces when comparing 2/2 micrometer (“micron”) trace width and spacing over legacy embodiments that used a solid dielectric between the traces.

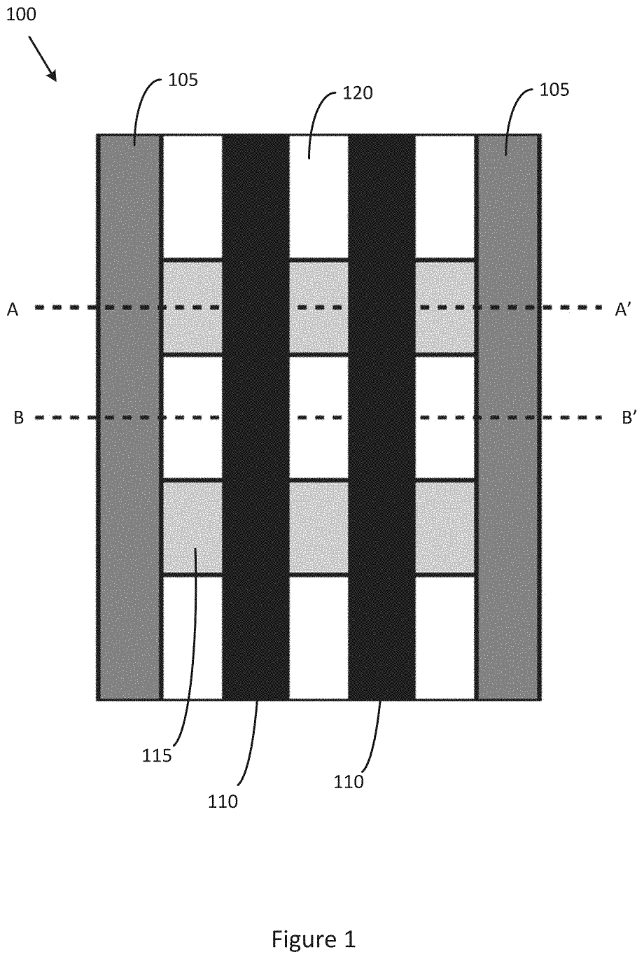

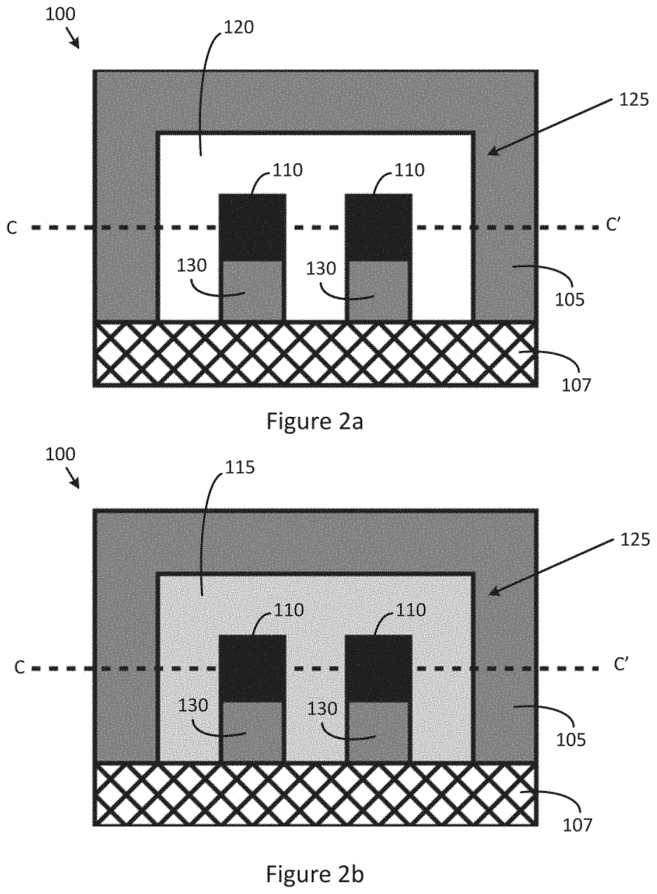

FIG. 1 depicts a simplified top-down view of an example interconnect stack 100 with a low-k dielectric, in accordance with various embodiments. FIGS. 2a and 2b depict simplified cross-sectional views of the example interconnect stack 100 with a low-k dielectric of FIG. 1, in accordance with various embodiments. Specifically, FIG. 1 depicts a top-down view of the example interconnect stack taken along lines C-C′ in FIGS. 2a and 2b. FIG. 2a depicts a simplified cross-sectional view along line B-B′ in FIG. 1. FIG. 2b depicts a simplified cross-sectional view along line A-A′ in FIG. 1.

It will be understood that FIG. 1, and other Figures herein, are intended as example Figures. For the sake of clarity of the Figures, each and every element of the Figures may not be specifically enumerated or described. However, it may be presumed, unless specifically stated to the contrary, that similar elements either within or between Figures may share characteristics with one another. Specifically, elements that are similarly shaped, shaded, etc. within Figures, or between Figures, may include characteristics that are similar to one another. It will further be understood that the specific shapes, relative sizes, etc. of the various elements may only be depicted herein as examples of a particular embodiment, and elements in other embodiments may have different shapes, sizes, etc. Other embodiments may have other variations than depicted.

The interconnect stack 100 may include a dielectric material 105. The dielectric material 105 may be, for example, a build-up film, a polymer, an organic build-up film, a photoimagable dielectric, a spin-on dielectric, a carbon-doped oxide, or some other dielectric material. Generally, the dielectric material 105 may be a material which may be laminated, spin coated, or otherwise deposited on a substrate 107 as shown in FIGS. 2a and 2b. In various embodiments, although the dielectric material 105 is depicted as a unitary piece of material, in some embodiments the dielectric material 105 may include two or more different types of dielectric layer. Similarly, in some embodiments the dielectric material 105 may be or include various layers of material or materials.

The substrate 107 may be, for example, considered to be a cored or coreless substrate. The substrate 107 may include one or more layers of a dielectric material which may be organic or inorganic. In some embodiments the substrate 107 may be, for example, a printed circuit board (PCB), an interposer, a motherboard, or some other type of substrate. In various embodiments, the substrate 107 may be or include metal coated on glass, flexible polymer, a silicon wafer, copper-clad laminate (CCL), an organic substrate, polyethylene terephthalate (PET), a dielectric similar to the dielectrics described with respect to the dielectric material 105, etc. In some embodiments, substrate 107 may include metal routing, vias, metal pads, or other features that are embedded in substrate, but not shown here for simplicity.

The dielectric material 105 and the substrate 107 may from a cavity 125. Within the cavity 125, the interconnect stack 100 may include a number of signal lines 110. The signal lines 110 may be formed of a conductive material such as copper, gold, or some other electrically conductive material. The signal lines 110 may allow for or facilitate the conveyance of an electronic signal (e.g., power, data, etc.) from one element of a microelectronic package that is coupled with a signal line 110 to another element of the microelectronic package. In some embodiments, the signal lines 110 may be referred to as a trace or a stripline. As used herein, the conductive elements within the cavity 125 will be referred to and described as traces or signal lines, however, in other embodiments the cavity 125 may additionally or alternatively include a different type of conductive elements such as a pad, a microstrip, a buried microstrip, a co-planar waveguide, a co-planar strip, etc.

The signal lines 110 may be positioned on pillars 130 within the cavity 125. As shown, the pillars 130 may be formed of the same material as the dielectric material 105. In other embodiments, the pillars 130 may be formed of the same material as the substrate 107. Generally, the pillars 130 may be formed during the formation of the interconnect stack 100 by using the signal lines 110 as an etch stop.

Specifically, in some embodiments the cavity 125 may be formed by placing a first layer of the dielectric material of the dielectric material 105 on the substrate 107. The dielectric material may be positioned on the substrate 107 through deposition, lamination, etc. The signal lines 110 may then be positioned on the dielectric material through, e.g., deposition, pick-and-place, or some other technique. The layered dielectric material may then be etched, for example, through chemical etching, optical etching, etc. The metal of the signal lines 110 may serve to protect the dielectric material that is immediately under the signal lines 110, which may result in the formation of the pillars 130. In some embodiments, the interconnect stack 100 may further include an etch stop layer positioned on the substrate 107 such that the etch stop layer is between the substrate 107 and the cavity 125/dielectric material 105/pillars 130. The etch stop layer is not pictured in FIGS. 1 and 2 for the sake of reducing clutter of the Figure, but may serve to protect the substrate 107 during the etch process.

The cavity 125 may be filled with one or more low-k dielectrics 120 and 125. The low-k dielectric 120 may be, for example, air, which may have a dielectric constant k of approximately 1. As may be seen, the low-k dielectric 120 may be positioned between elements of the interconnect stack such as the signal lines 110 and the pillars 130. The portion of air between the various elements may be referred to herein as an “air-gap.”

The other low-k dielectric 115 may be, for example, a porous dielectric material with a dielectric constant k of between approximately 1.5 and 2. Such a material may be, for example, carbon-doped oxide or some other material. The use of the porous dielectric material may be desirable to provide structural stability to the interconnect stack 100 by intermittently filling the cavity 125 such that the cavity 125 does not have an extended air-gap. It will be understood, however, that this embodiment is intended as one example embodiment, and other embodiments may have a different number of low-k or ultra-low-k dielectrics, dielectrics with different dielectric constants k below approximately 3.9, a different arrangement of dielectrics within the cavity, etc.

Generally, the embodiment of FIGS. 1 and 2a/2b may be desirable, because it may reduce, mitigate, eliminate, or otherwise affect the aspects of the interconnect stack 100 such as RC-delay, crosstalk, or dynamic power consumption. Specifically, because the signal lines 110 are separated from one another by dielectrics such as low-k dielectrics 120 and 115, crosstalk between the signal lines 110 may be significantly reduced as described above. Additionally, because the signal lines 110 are generally surrounded by the low-k dielectrics on at least three sides of the signal lines 110, the crosstalk between the signal lines may be mitigated, and capacitance may be decreased. Additionally, because the cavity dielectric material 105 on which the signal lines 110 are positioned (e.g., the pillars 130) is separated by the low-k dielectrics 120/115, crosstalk may be further reduced and capacitance may be decreased due to reduction in fringing effects through the dielectric material 105 or the substrate 107.

As noted, it will be understood that the interconnect stack 100 is intended as a highly simplified embodiment, and other embodiments may include more elements than depicted. For example, in some embodiments the interconnect stack 100 may include one or more additional active elements (e.g., a logic, a memory, a radio frequency (RF)-filter, etc.), passive elements (e.g., a resistor, capacitor, inductor, etc.), or conductive elements (e.g., a trace, a pad, a via, etc.). The additional elements may be within the cavity 125, a part of the substrate 107, etc. In some embodiments, the air-gaps may improve the electric performance of the RF-related elements (e.g., inductors or filters). For example, introducing air-gaps between the traces forming a planar spiral inductor may reduce winding capacitance, thereby increasing the self-resonant frequency and quality-factor of the inductor.

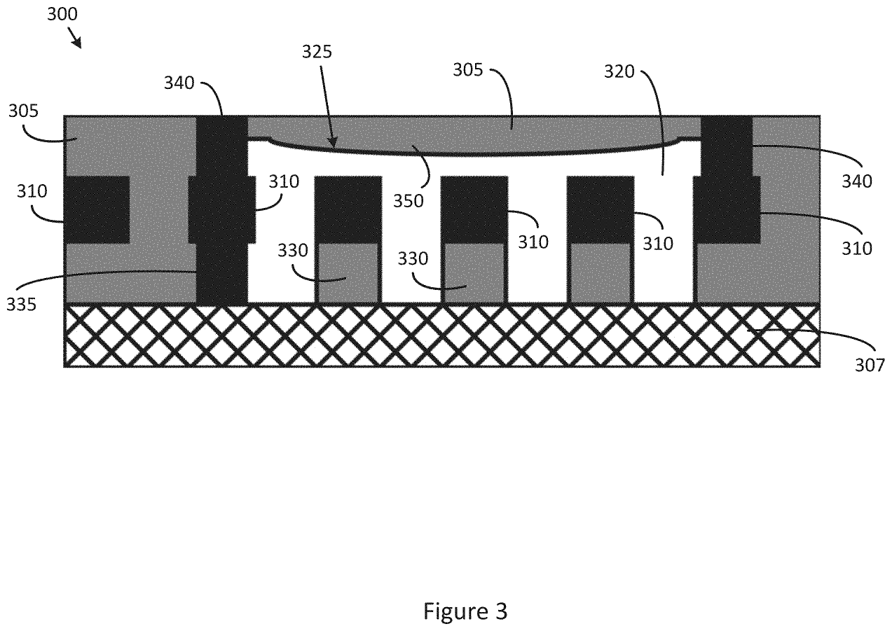

FIGS. 3-8 depict simplified cross-sectional views of an alternative example interconnect stack with a low-k dielectric, in accordance with various embodiments. Generally, the FIGS. 3-8 depict alternative embodiments with structures that are similar to, and may share one or more characteristics with, structures of FIG. 1 or 2a/2b. It will be understood that each and every element of FIGS. 3-8 are not specifically enumerated herein for the sake of lack of redundancy and clutter, however elements that are generally identical to elements of FIG. 1 or 2a/2b in terms of shading or appearance may share characteristics with those elements of the previous Figures unless there is a statement to the contrary.

It will also be understood that FIGS. 3-8 are intended as highly simplified Figures which may be related to embodiments that may include additional active, passive, or conductive elements that are not depicted in the Figures for the sake of lack of clutter. Additionally, it will be understood that the Figures are related to sample embodiments and other embodiments may include a different number of elements, elements with a different shape or relative size, elements in a different configuration, etc.

Additionally, it will be understood that although the various cavities of the Figures are described as including a low-k dielectric similar to low-k dielectric 120, in other embodiments the cavities may additionally or alternatively include a different low-k dielectric such as low-k dielectric 115 or some other low-k dielectric or ultra-low-k dielectric with a dielectric constant k of less than approximately 3.9, as described above.

Additionally, it will be noted that certain elements may be omitted from various embodiments. For example, some embodiments may not include pillars, and instead substrate may not include air-gaps between the portions of the substrate on which the signal lines are positioned. Finally, it will be understood that the embodiments of FIGS. 3-8 are intended as example embodiments and other embodiments of the present disclosure may include combinations of various of the described interconnect stacks. For example, various embodiments may include combinations of various dielectric features, specific structures of the dielectric material or substrate, conductive planes, protection plates, etc. as described below.

FIG. 3 depicts an interconnect stack 300 which may be similar to, and share one or more characteristics with, interconnect stack 100. The interconnect stack 300 may include a substrate 307 with a dielectric material 305 positioned thereon, which may be respectively similar to, and share one or more characteristics with, substrate 107 and dielectric material 105. The interconnect stack 300 may include a number of signal lines 310 and pillars 330 which may be respectively similar to, and share one or more characteristics with, signal lines 110 and pillars 130. The signal lines 310 and pillars 330 may be positioned in a cavity 325 filled with a low-k dielectric 320 (e.g., air), which may be respectively similar to, and share one or more characteristics with, cavity 125 and low-k dielectric 120.

The interconnect stack 300 may be referred to as a multi-layer interconnect stack, similarly to interconnect stack 100. In the embodiment of FIG. 3, the interconnect stack 300 may include three layers, although it will be understood that other embodiments may have more or fewer layers. Specifically, the interconnect stack 300 may include a middle layer of signal lines 310. The interconnect stack 300 may further include a layer of down-vias 335 and a layer of up-vias 340. The up-vias 340 and down-vias 335 may be conductive elements formed of a material such as gold, copper, etc. which allow for signal routing or communication between layers of the interconnect stack 300 or a microelectronic package of which the interconnect stack 300 is a part. Specifically, the up-vias 340 may communicatively couple a signal line 310 with an element coupled with the top of the interconnect stack 300 (as oriented in FIG. 3). The down-vias 335 may couple a signal line 310 with the substrate 307 (or an element therein).

In some embodiments, the signal lines 310 may not be coupled with a via for a given cross-section such as the one depicted in FIG. 3. An example of such a signal line are the ones positioned within the cavity 325. In some embodiments, a signal line 310 may be fully surrounded by the dielectric material 305, as may be seen with respect to the signal line 310 at the left side of the interconnect stack 300 (as oriented in FIG. 3). In some embodiments, a signal line 310 may be coupled only with an up-via 340, may be coupled with both an up-via 340 and a down-via 335, or only a down-via 335 (not shown). Other variations may be present in other embodiments.

The interconnect stack 300 may further include a layer of dielectric material 305 at a top portion of the cavity 325, and the dielectric material 305 may include a dielectric feature 350. In the embodiment of FIG. 3, the dielectric feature 350 may be a convex protrusion of the dielectric material 305 into the cavity. The dielectric feature 350 may provide a number of benefits. For example, the dielectric feature 350 may change the amount of the low-k dielectric 320 within the cavity 325, thereby affecting aspects of the interconnect stack 300 such as the capacitance, crosstalk, etc. In some embodiments, the dielectric feature 350 may be formed through selection of the material used for the dielectric material 305. For example, the specific stiffness or conformity of the dielectric material 305, dimensions of the various signal lines 310 or vias 335/340, technique for positioning the dielectric material 305, etc. may change the particular shape or structure of the dielectric material 305 and, particularly, the dielectric feature 350.

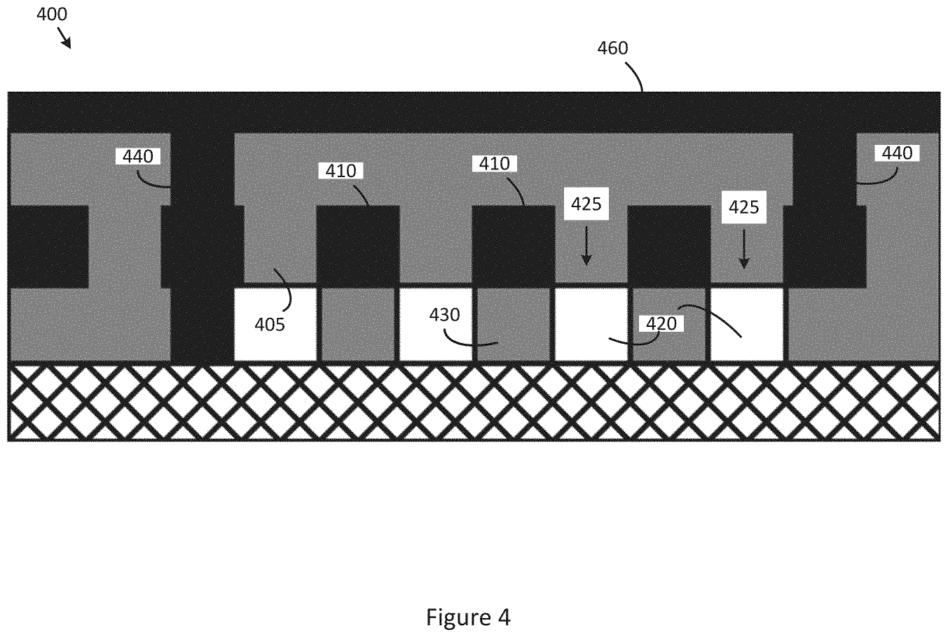

FIG. 4 depicts an interconnect stack 400 with signal lines 410, pillars 430, and dielectric material 405 which may be respectively similar to, and share one or more characteristics with, signal lines 110, pillars 130, and dielectric material 105. As may be seen, the dielectric material 405 may be generally positioned between the signal lines 410, which may result in the cavity 425 (which may be similar to cavity 125) being primarily between the pillars 430 as shown in FIG. 4. The cavity 425 may be filled with a low-k dielectric 420 which may be similar to low-k dielectric 120 of FIG. 1. It will be understood that this is one example embodiment and, in other embodiments, the dielectric material 405 may only be positioned partially between the signal lines 410 so that there is both the low-k dielectric 420 and the dielectric material 405 positioned between various of the signal lines 410. In other embodiments, the dielectric material 405 may extend beyond the signal lines 410 so that there is both low-k dielectric 420 and dielectric material 405 positioned between various of the pillars. Other embodiments may have other variations.

As may be seen, the interconnect stack 400 may include a conductive plane 460 which may be communicatively coupled with up-vias 440 (which may be similar to, and share one or more characteristics with, up-vias 340). The conductive plane 460 may be formed of a conductive material such as copper, gold, etc. In some embodiments, the conductive plane 460 may be implemented as a unitary plate structure in the substrate of the microelectronic package that includes the interconnect stack 400, while in other embodiments the conductive plane 460 may be implemented as a number of traces/pads/vias/etc. The conductive plane 460 may allow communicative coupling of other elements of the microelectronic package with the signal lines 410 via the up-vias 440, communicative coupling between two signal lines 410, or some other type of communicative coupling.

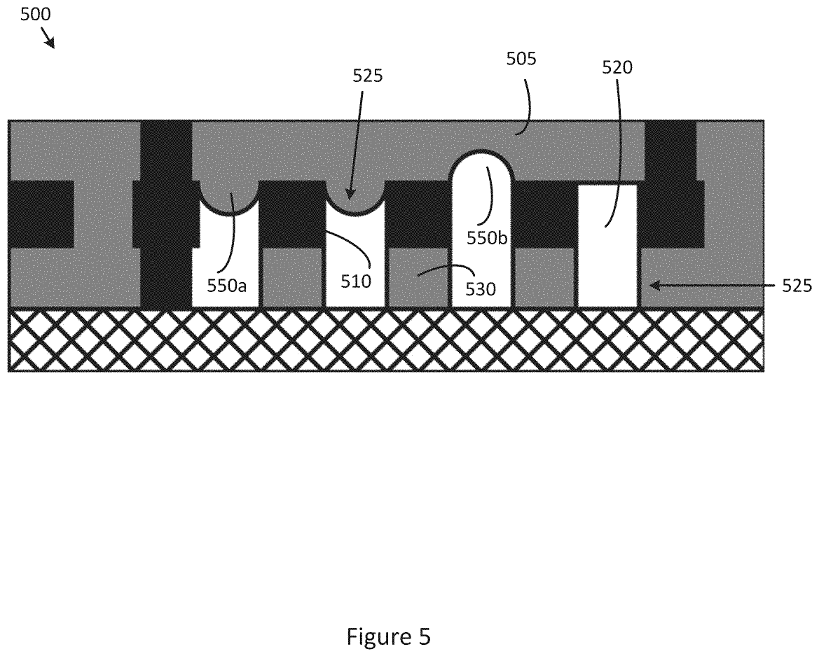

FIG. 5 depicts an interconnect stack 500 with a dielectric material 505, a number of signal lines 510, and a number of pillars 530 which may be respectively similar to, and share one or more characteristics with, dielectric material 105, signal lines 110, and pillars 130. As may be seen, the dielectric material 505 may be physically coupled with the top of the signal lines 510 as shown in FIG. 5. As a result, the interconnect stack 500 may include a number of cavities 525 which may be similar to, and share one or more characteristics with, cavities 125. The cavities 525 may be filled with a low-k dielectric 520 which may be similar to low-k dielectric 120 or some other dielectric discussed herein.

As may be seen, the dielectric material 505 may include a number of dielectric features 550a and 550b, which may be similar to, and share one or more characteristics with, dielectric feature 350. The dielectric feature 550a may be a convex protrusion of the dielectric material 505 into a cavity 525. The dielectric feature 550b may be a concave aspect to the dielectric material 505 which may extend the cavity 525 at least partially into the dielectric material. As may be seen in the rightmost cavity 525, the dielectric material 505 may not include a dielectric feature, but rather may be relatively straight. It will be understood that these embodiments of the features are intended as examples, and other embodiments may have dielectric features with a different cross-sectional profile, a different arrangement of dielectric features, etc.

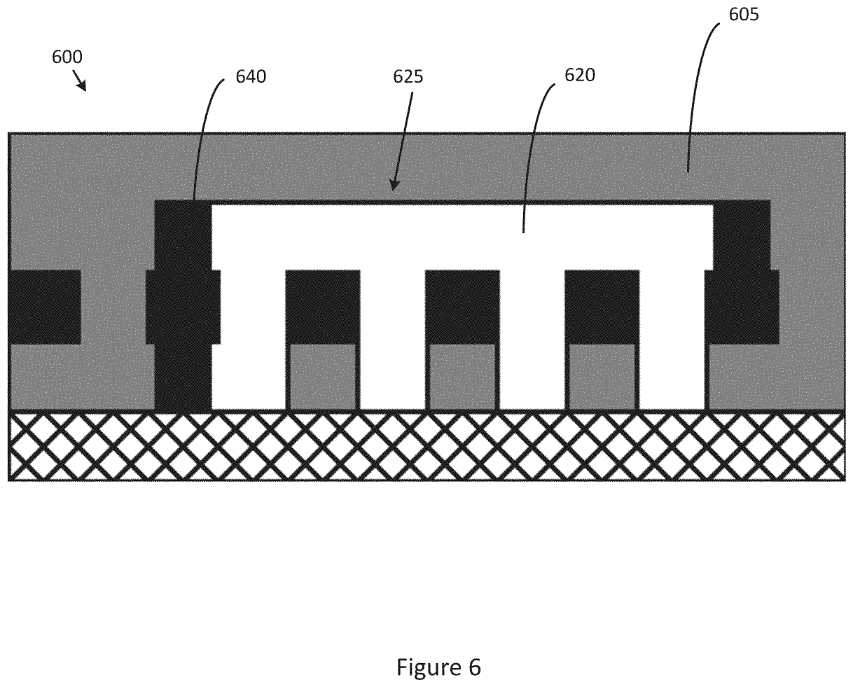

FIG. 6 depicts an alternative view of an interconnect stack 600 which may include a dielectric material 605, an up-via 640, and a cavity 625 which may be respectively similar to, and share one or more characteristics with, dielectric material 105, up-via 340, and cavity 125. The cavity 625 may be filled with a low-k dielectric 620 which may be similar to, and share one or more characteristics with, low-k dielectric 120. As may be seen, in this embodiment the interconnect stack may include an additional layer wherein the dielectric material 605 is positioned above the up-via 640 rather than adjacent to it within the cavity 625 as depicted in other embodiments. This embodiment may create an air-gap between the various up-vias 640, which may even further mitigate crosstalk and decrease capacitance. It will be understood that in this embodiment, signal routing may still occur through the dielectric material 605 by way of one or more conductive elements, a conductive plane, or other elements. Additionally, in some embodiments the dielectric material 605 may extend partially into the cavity along the up-vias 640 so that the up-vias 640 are partially exposed to the cavity 625 and partially encapsulated by the dielectric material 605. Other variations may be present in other embodiments.

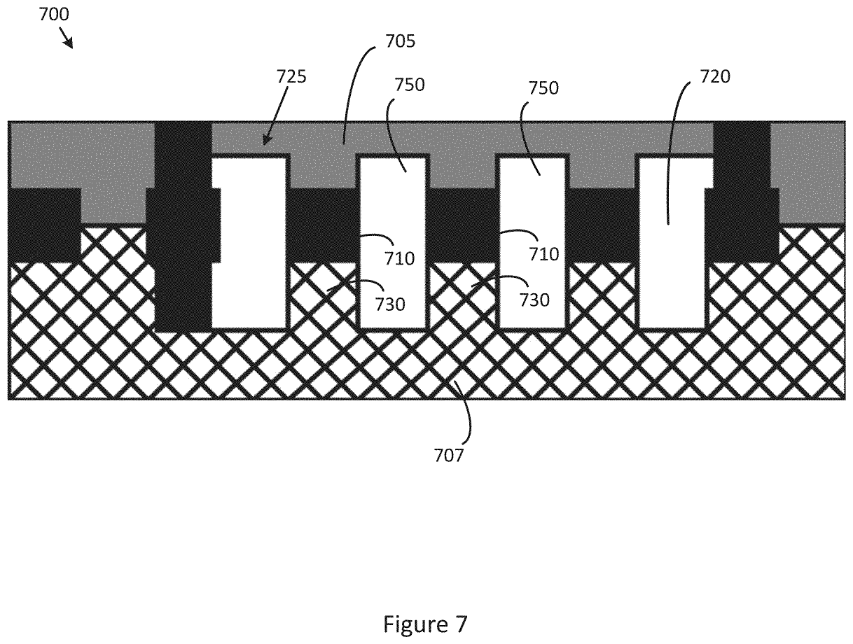

FIG. 7 depicts an example interconnect stack 700 which may include one or more signal lines 710, a substrate 707, a dielectric material 705, pillars 730, and cavities 725, which may be respectively similar to, and share one or more characteristics with, signal lines 110, substrate 107, dielectric material 105, pillars 130, and cavities 125. In this embodiment, as may be seen, the cavities 725 may extend at least partially into the substrate 707. The cavities 725 may be filled with a low-k dielectric 720 which may be similar to, and share one or more characteristics with, dielectric 120. In that manner, pillars 730 may be formed of the material of the substrate 707 rather than the material of the dielectric material 705 as may be depicted in other embodiments. Such a cavity 725 may be formed through positioning the signal lines 710 directly on the substrate 707 and then performing the etching without the addition of an etch stop layer on the substrate 707. In some embodiments, an etching process may be performed prior to adding the signal lines 710, so that the signal lines 710 may be at least partially within or at least partially surrounded by the substrate 707 as depicted in FIG. 7.

Further, in this embodiment, the dielectric material 705 may be selectively laminated such that dielectric features 750 may be formed. Specifically, in this embodiment the dielectric features 750 may be such that the cavities 725 further extend into the dielectric material 705 thereby decreasing the capacitance and reducing crosstalk within the interconnect stack 700.

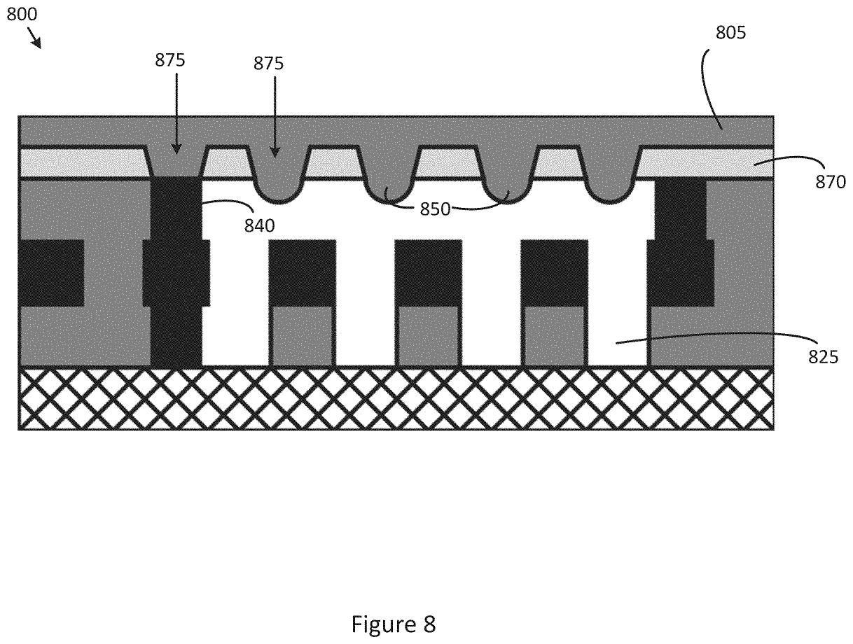

FIG. 8 depicts an alternative interconnect stack 800 with a cavity 825 within dielectric material 805 which may be respectively similar to, and share one or more characteristics with, cavity 125 and dielectric material 105. In some embodiments, the interconnect stack 800 may include a protection layer 870 with one or more holes 875 therein, which may be referred to as “adhesion holes.” In this embodiment, the cavity 825 may be formed through filling the cavity 825 with a thermally decomposable material. The protection layer 870 may then be positioned over the cavity and the interconnect stack 800 may be exposed to heat. The thermally decomposable material may decompose to a gas, which may exit the cavity 825 through the holes 875. The top layer of the dielectric material 805 (as oriented in FIG. 8) may then be positioned on the protection layer 870. In some embodiments, the top dielectric material 805 may at least partially flow through the holes 875 to form dielectric features 850 that at least partially protrude within the cavity 825.

It will also be noted that the protection layer 870 may include a hole 875 that is not adjacent to the cavity, but is adjacent to up-via 840 (which may be similar to, and share one or more characteristics with, up-via 340). In this embodiment, the hole 875 may allow for signal routing from the up-via 840 through the protection layer to various passive/active/conductive elements which may be present in the interconnect stack 800, or to other elements of a microelectronic package of which the interconnect stack 800 is a part.

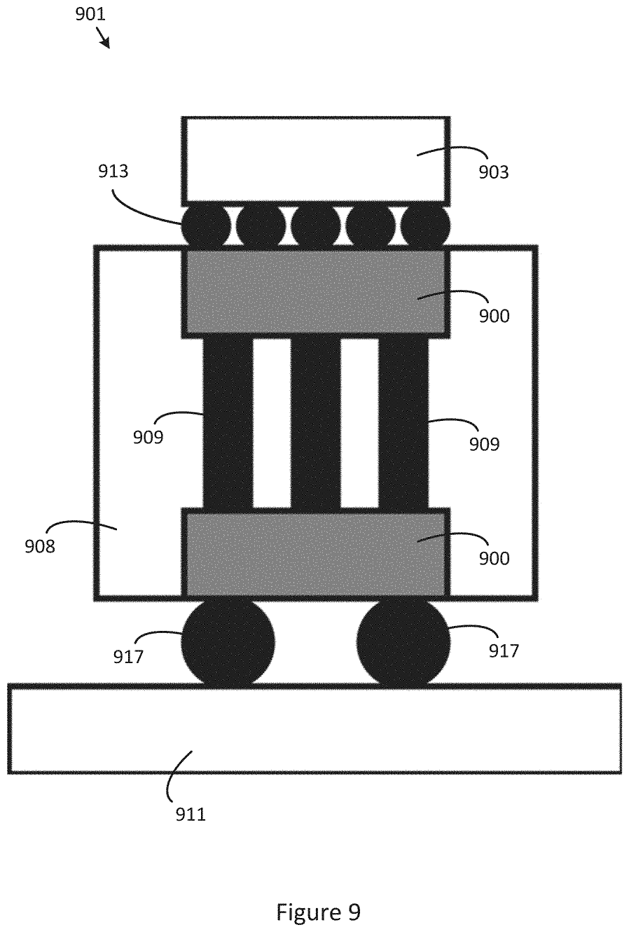

FIG. 9 depicts an example microelectronic package 901 which may include one or more interconnect stacks 900 therein. Specifically, the microelectronic package 901 may include a package substrate 908 which may be similar to one or more of the above-described package related materials such as the dielectric material 105, the substrate 107, or some other dielectric material or substrate described herein. Specifically, the package substrate 908 may be, for example, considered to be a cored or coreless substrate. The package substrate 908 may include one or more layers of a dielectric material which may be organic or inorganic. The package substrate 908 may further include one or more conductive elements such as vias, pads, traces, microstrips, striplines, etc. The conductive elements may be internal to, or on the surface of, the package substrate. Generally, the conductive elements may allow for the routing of signals through the package substrate 908, or between elements that are coupled to the package substrate 908. In some embodiments the package substrate 908 may be, for example, an interposer or some other type of substrate. In some embodiments the package substrate 908 may include one or more additional conductive elements, passive elements, or active elements which are not shown in FIG. 9 for the sake of simplicity of the Figure.

An interconnect stack 900, which may be similar to interconnect stack 100 or some other interconnect stack described herein, may be positioned at either side of the package substrate 908. The interconnect stacks 900 may be communicatively coupled to one another through the package substrate 908 by one or more conductive elements 909 (represented as vias, but which could include one or more vias, pads, traces, etc.). The conductive elements 909 may be formed of a conductive material such as gold, copper, etc., and may allow for communication between opposite sides of the package substrate 908 and, more specifically, between elements of the interconnect stacks 900.

The microelectronic package 901 may further include an active die 903. The active die 903 may be or include, for example, a processor such as a central processing unit (CPU), graphics processing unit (GPU), a core of a distributed processor, or some other type of processor. Alternatively, the active die 903 may be include a memory such as a double data rate (DDR) memory, a nonvolatile memory (NVM), a volatile memory, a read-only memory (ROM), or some other type of memory or die. In some embodiments the active die 903 may be or include an RF chip or RF circuitry that is configured to generate, process, transmit, or receive a wireless signal such as a third generation (3G), a fourth generation (4G), a fifth generation (5G), a Wi-Fi, or some other type of wireless signal. In some embodiments the active die 903 may include one or more passive components such as capacitors, resistors, etc. The various active or passive components may be positioned within, partially within, or on the surface of the active die 903.

The active die 903 may be coupled with the package substrate 908, and particularly an interconnect stack 900 of the package substrate 908, but one or more interconnects 913. The interconnects 913 may be, for example, solder bumps that are formed of a material such as tin, silver, copper, etc. If solder bumps are used for the interconnects 913, then the solder bumps may be elements of a ball grid array (BGA) as shown in FIG. 9. In other embodiments, the interconnects 913 may be pins of a pin grid array (PGA), elements of a land grid array (LGA), or some other type of interconnect. Generally, the interconnects 913 may physically or communicatively couple the active die 903 with the package substrate 908. For example, one or more of the interconnects 913 may physically couple with, and allow electrical signals to pass between, pads of the active die 903 and pads of the package substrate 908 (the pads not shown for the sake of elimination of clutter of FIG. 9). In other embodiments, the interconnects 913 may physically couple the active die 903 to the package substrate 908, but one or more of interconnects 913 may not communicatively couple the active die 903 and the package substrate 908.

The microelectronic package 901 may further include a number of interconnects 917, which may be similar to, and share one or more characteristics with, interconnects 913. Specifically, the interconnects 917 may be elements of a BGA, a PGA, an LGA, etc. In some embodiments, the interconnects 917 may be replaced by a socket or some other coupling structure. The interconnects 917 may communicatively or physically couple the microelectronic package 901 to a PCB 911 which may be, for example, a motherboard, an interposer, a circuit board, or some other type of PCB 911 of an electronic device.

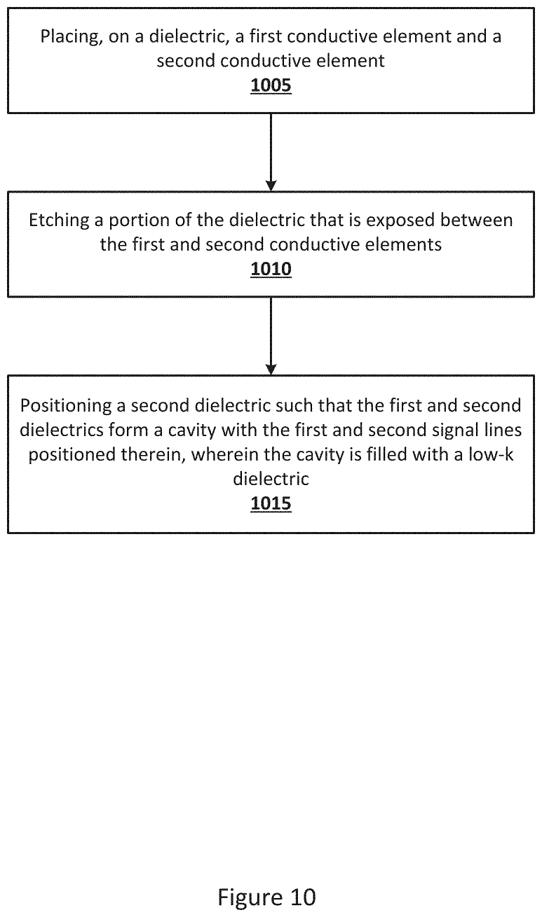

FIG. 10 depicts an example technique by which an interconnect stack with a low-k dielectric may be manufactured, in accordance with various embodiments. It will be understood that the technique of FIG. 10 is a highly simplified technique and may be related to various processing techniques described above with respect to various Figures. Real-world embodiments may include significantly more elements such as photoresist deposition or patterning, plasma etching, seed etch, etc. Additionally, in real-world embodiments, certain elements may be performed in an order different than depicted, concurrently with one another, or certain elements (e.g. element 1010) may be omitted. In general, FIG. 10 will be described with respect to elements of the interconnect stack 100, although it will be understood that other embodiments may be applicable, in whole or in part, with or without modification, to other embodiments of the present disclosure either explicitly shown in the various Figures or related to the described embodiments.

The technique may include placing, at 1005, on a dielectric, a first conductive element and a second conductive element. The dielectric may be similar to, for example, substrate material 107 or dielectric material 105. In the particular embodiment of interconnect stack 100, the dielectric may be the dielectric material that forms the pillars 130. The conductive elements may be signal lines 110, however as noted above, in other embodiments the conductive elements may be some other type of conductive elements such as microstrips, buried microstrips, co-planar waveguides, co-planar strips, etc.

The technique may further include etching, at 1010, a portion of the dielectric that is exposed between the first and second conductive elements. As described above, the etch may be a chemical etch, a mechanical etch, a plasma etch, or some other type of subtractive process. The etching of the dielectric may form the pillars 130 and, more particularly, allow for the air-gaps between the conductive elements and the pillars as shown in FIG. 2a.

The technique may further include positioning, at 1015, a second dielectric such that the first and second dielectrics form a cavity with the first and second signal lines positioned therein, wherein the cavity is filled with a low-k dielectric. The second dielectric may be, for example, dielectric material 105 which helps define the cavity 125. The low-k dielectric may be similar to, for example, low-k dielectrics 120 or 115, or some other low-k dielectric discussed herein.

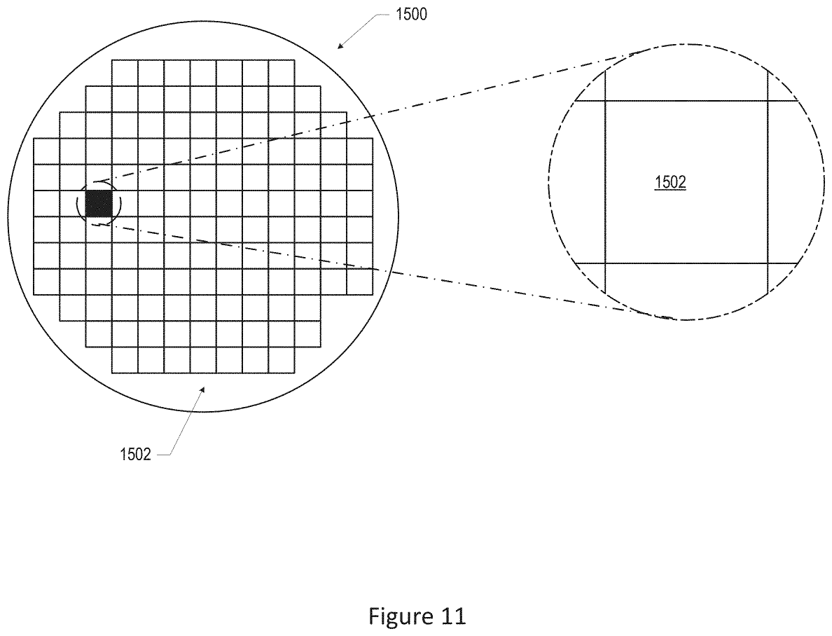

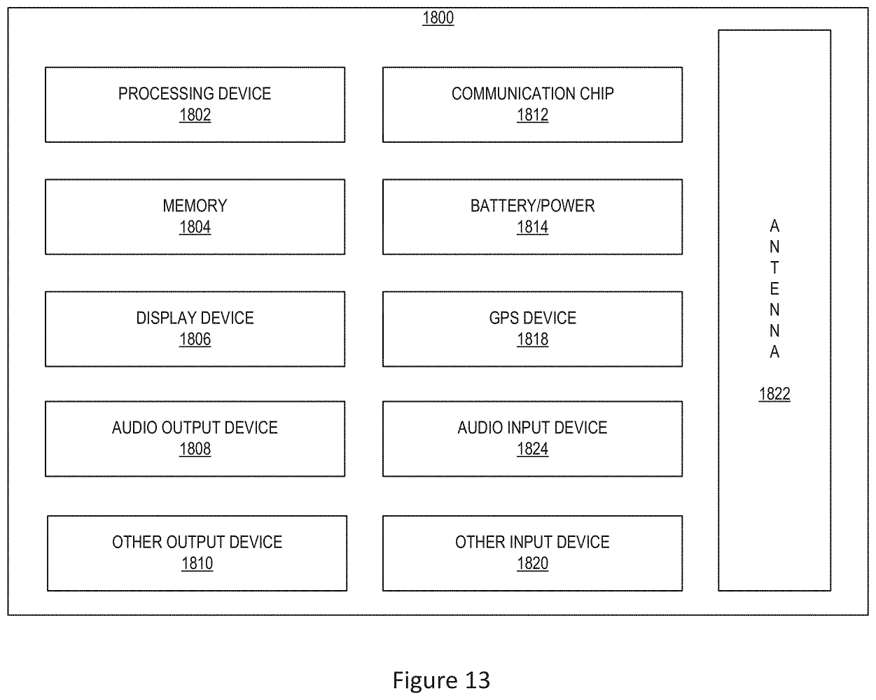

FIG. 11 is a top view of a wafer 1500 and dies 1502 that may include one or more interconnect stacks with a low-k dielectric, or may be included in an IC package including one or more interconnect stacks with a low-k dielectric in accordance with various embodiments. The wafer 1500 may be composed of semiconductor material and may include one or more dies 1502 having IC structures formed on a surface of the wafer 1500. Each of the dies 1502 may be a repeating unit of a semiconductor product that includes a suitable IC. The dies 1502 may not be square and/or be of the same size. After the fabrication of the semiconductor product is complete, the wafer 1500 may undergo a singulation process in which the dies 1502 are separated from one another to provide discrete “chips” of the semiconductor product. The die 1502 may include one or more interconnect stacks with a low-k dielectric, one or more transistors or supporting circuitry to route electrical signals to the transistors, or some other IC component. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 13) or other logic that is configured to store information in the memory devices or execute instructions stored in the memory array.

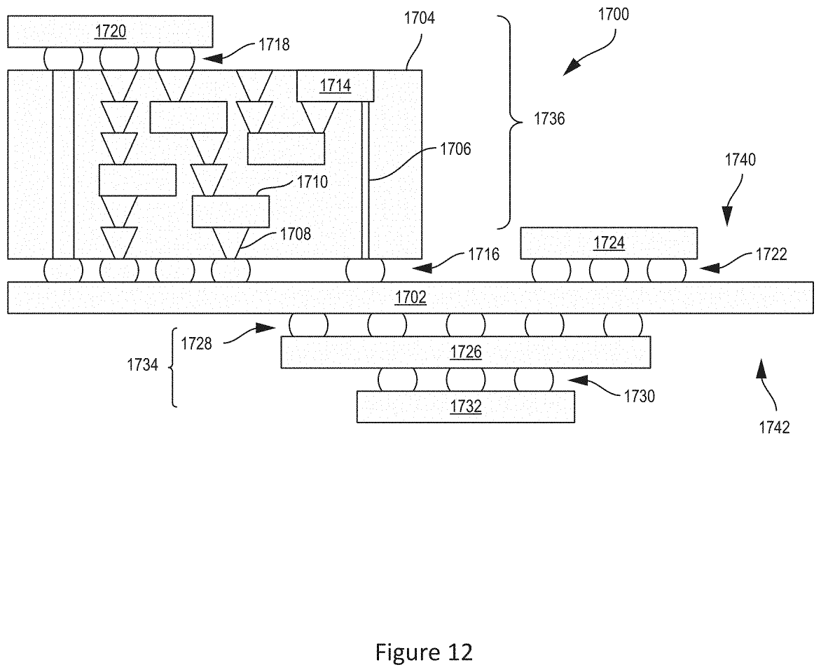

FIG. 12 is a side, cross-sectional view of an IC device assembly 1700 that may include one or more IC packages or other electronic components (e.g., a die) including one or more interconnect stacks with a low-k dielectric, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 12 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 12), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 12, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 12, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more interconnect stacks with a low-k dielectric.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 12 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 13 is a block diagram of an example electrical device 1800 that may include one or more interconnect stacks with a low-k dielectric, in accordance with any of the embodiments disclosed herein. For example, any suitable ones of the components of the electrical device 1800 may include one or more of the IC device assemblies 1700, IC packages, IC devices, or dies 1502 disclosed herein. A number of components are illustrated in FIG. 13 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 13, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), CPUs, GPUs, cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., ROM), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute of Electrical and Electronics Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., alternating current (AC) line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### Examples of Various Embodiments

Example 1 includes a microelectronic package comprising: an interconnect stack with a cavity therein, wherein the cavity includes a dielectric material with a dielectric value less than 3.9; a first conductive element in the cavity; and a second conductive element in the cavity, wherein the dielectric material is positioned between the first and second conductive elements.

Example 2 includes the microelectronic package of example 1, wherein the dielectric material has a dielectric value less than or equal to 2.

Example 3 includes the microelectronic package of example 1, wherein the dielectric material is air.

Example 4 includes the microelectronic package of example 3, wherein the dielectric material has a dielectric value of approximately 1.

Example 5 includes the microelectronic package of example 1, wherein the dielectric material is an inert gas.

Example 6 includes the microelectronic package of example 5, wherein the inert gas includes nitrogen or argon.

Example 7 includes the microelectronic package of any of examples 1-6, wherein the first conductive element is a conductive trace.

Example 8 includes the microelectronic package of any of examples 1-6, wherein the dielectric material is in contact with a first side of the first conductive element and a second side of the first conductive element, wherein the first side of the first conductive element is opposite the second side of the first conductive element.

Example 9 includes the microelectronic package of example 8, wherein the dielectric material is further in contact with a third side of the first conductive element that is adjacent to the first and second sides of the first conductive element.

Example 10 includes an interconnect stack for use in a microelectronic package, wherein the interconnect stack comprises: a dielectric material; a substrate; a first signal line coupled with the substrate between the substrate and the dielectric material; a second signal line coupled with the substrate between the substrate and the dielectric material; and a low-k dielectric with a dielectric value less than 2 between the first signal line and the second signal line.

Example 11 includes the interconnect stack of example 10, wherein the low-k dielectric is a gas with a dielectric value of approximately 1.

Example 12 includes the interconnect stack of example 10, wherein the dielectric material is physically coupled with the first and second signal lines.

Example 13 includes the interconnect stack of example 12, wherein the dielectric material is further partially between the first and second signal lines.

Example 14 includes the interconnect stack of example 12, wherein the low-k dielectric extends partially into the substrate.

Example 15 includes the interconnect stack of example 12, wherein the low-k dielectric extends partially into the dielectric material.

Example 16 includes the interconnect stack of any of examples 10-15, wherein the low-k dielectric is air.

Example 17 includes the interconnect stack of any of examples 10-15, wherein the dielectric material is an inert gas.

Example 18 includes the interconnect stack of example 17, wherein the inert gas is nitrogen, argon, or a combination of inert gases.

Example 19 includes an electronic device comprising: a substrate; and a microelectronic package coupled with the substrate, wherein the microelectronic package includes: a dielectric with a cavity therein; a protection layer adjacent to the cavity; a plurality of signal lines in the cavity; and a low-k material with a dielectric value less than 3.6 in the cavity, wherein the low-k material is between two signal lines of the plurality of signal lines.

Example 20 includes the electronic device of example 19, wherein the ceiling protection layer includes an adhesion hole, and wherein the dielectric extends into the cavity through the adhesion hole.

Example 21 includes the electronic device of example 19, wherein the low-k material has a dielectric value of less than 1.5.

Example 22 includes the electronic device of any of examples 19-21, wherein the low-k material is air.

Example 23 includes the electronic device of any of examples 19-21, wherein the dielectric material is an inert gas.

Example 24 includes the electronic device of example 23, wherein the inert gas is nitrogen, argon, or a combination of inert gases.

Example 25 includes the electronic device of any of examples 19-21, wherein the microelectronic package includes a first via and a second via in the dielectric layer, wherein the signal line is between the first and second vias.

Example 26 includes the electronic device of example 25, wherein the protection layer includes an adhesion hole adjacent to the first via.

Example 27 includes a method of forming a microelectronic package, wherein the method comprises: placing, on a dielectric, a first conductive element and a second conductive element; etching a portion of the dielectric that is exposed between the first and second conductive elements; and positioning a second dielectric such that the first and second dielectrics form a cavity with the first and second signal lines positioned therein, wherein the cavity is filled with a low-k dielectric that has a dielectric value less than 3.9.

Example 28 includes the method of example 27, wherein the low-k dielectric has a dielectric value less than 2.

Example 29 includes the method of example 27, wherein the low-k dielectric has a dielectric value of approximately 1.

Example 30 includes the method of any of examples 27-29, wherein the low-k dielectric is air.

Example 31 includes the method of any of examples 27-29, wherein the dielectric material is an essentially inert gas.

Example 32 includes the method of example 31, wherein the essentially inert gas is nitrogen, argon, or combination of inert gases.

Example 33 includes the method of any of examples 27-29, wherein the first and second dielectrics are formed of a same material as each other.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A microelectronic package comprising:
an interconnect stack with a cavity therein, wherein the cavity includes a dielectric material with a dielectric value less than 3.9;
a first conductive element in the cavity; and
a second conductive element in the cavity, wherein the dielectric material is positioned between the first and second conductive elements.

2. The microelectronic package of claim 1, wherein the dielectric material has a dielectric value less than or equal to 2.

3. The microelectronic package of claim 1, wherein the dielectric material is air.

4. The microelectronic package of claim 3, wherein the dielectric material has a dielectric value of approximately 1.

5. The microelectronic package of claim 1, wherein the dielectric material is an inert gas.

6. The microelectronic package of claim 1, wherein the first conductive element is a conductive trace.

7. The microelectronic package of claim 1, wherein the dielectric material is in contact with a first side of the first conductive element and a second side of the first conductive element, wherein the first side of the first conductive element is opposite the second side of the first conductive element.

8. The microelectronic package of claim 7, wherein the dielectric material is further in contact with a third side of the first conductive element that is adjacent to the first and second sides of the first conductive element.

9. An interconnect stack for use in a microelectronic package, wherein the interconnect stack comprises:
a dielectric material;
a substrate;
a first signal line coupled with the substrate between the substrate and the dielectric material;
a second signal line coupled with the substrate between the substrate and the dielectric material; and
a low-k dielectric with a dielectric value less than 2 between the first signal line and the second signal line.

10. The microelectronic package of claim 9, wherein the low-k dielectric is a gas with a dielectric value of approximately 1.

11. The microelectronic package of claim 9, wherein the dielectric material is physically coupled with the first and second signal lines.

12. The microelectronic package of claim 11, wherein the dielectric material is further partially between the first and second signal lines.

13. The microelectronic package of claim 11, wherein the low-k dielectric extends partially into the substrate.

14. The microelectronic package of claim 11, wherein the low-k dielectric extends partially into the dielectric material.

15. The microelectronic package of claim 9, wherein the dielectric material is an inert gas that includes nitrogen or argon.

16. An electronic device comprising:
a substrate; and
a microelectronic package coupled with the substrate, wherein the microelectronic package includes:
a dielectric with a cavity therein;
a protection layer adjacent to the cavity;
a plurality of signal lines in the cavity; and
a low-k material with a dielectric value less than 3.6 in the cavity, wherein the low-k material is between two signal lines of the plurality of signal lines.

17. The electronic device of claim 16, wherein the protection layer includes an adhesion hole, and wherein the dielectric extends into the cavity through the adhesion hole.

18. The electronic device of claim 16, wherein the low-k material has a dielectric value of less than 1.5.

19. The electronic device of claim 16, wherein the microelectronic package includes a first via and a second via in the dielectric, wherein the signal line is between the first and second vias.

20. The electronic device of claim 19, wherein the protection layer includes an adhesion hole adjacent to the first via.
